(19) United States
(12) Patent Application Publication
(10) Pub. No.: US 2012/0086054 A1
(43) Pub. Date: Apr. 12, 2012

(54) SEMICONDUCTOR STRUCTURE AND METHOD FOR MAKING THE SAME

(76) Inventors: Tzyy-Ming Cheng, Hsinchu City (TW); Meng-Chi Tsai, Nantou County (TW); Tsai-Fu Chen, Hsinchu City (TW); Ta-Kang Lo, Taoyuan County (TW); Wen-Han Hung, Kaohsiung City (TW); Shih-Fang Tzou, Hsinchu County (TW); Chun-Yuan Wu, Yunlin County (TW)

(21) Appl. No.: 12/902,159

(22) Filed: Oct. 12, 2010

(51) Int. Cl. H01L 29/78; H01L 21/336

(52) U.S. Cl. 257/288; 438/301; 257/E29.255; 257/E21.409

(57) ABSTRACT

A semiconductor structure is disclosed. The semiconductor structure includes a gate structure disposed on a substrate, a source and a drain respectively disposed in the substrate at two sides of the gate structure, a source contact plug disposed above the source and electrically connected to the source and a drain contact plug disposed above the drain and electrically connected to the drain. The source contact plug and the drain contact plug have relatively asymmetric element properties.

### BACKGROUND OF THE INVENTION

1. Field of the Invention

The present invention generally relates to a semiconductor structure and the method for making the same. In particular, the present invention is directed to a semiconductor structure whose source contact plug and drain contact plug have relatively asymmetric element properties as well as a method for fabricating a semiconductor structure.

2. Description of the Prior Art

In a regular semiconductor structure, a gate structure is used to control the on and off state of a current passing through the source and the drain which are disposed at two sides of the gate structure. Because the source and the drain are respectively disposed in the substrate at two sides of the gate structure and covered by an interlayer dielectric layer, a source contact plug and a drain contact plug are still needed to respectively penetrate the interlayer dielectric layer to form an electrical connection of the source and the drain to an outer circuit.

In order to increase the operational performance of the semiconductor elements, a conductive material of lower electric resistance, such as metals, is usually used in the source contact plug and the drain contact plug. Besides, traditionally each one of a single semiconductor element uses an independent source contact plug and an independent drain contact plug to independently control the semiconductor element. That is, in the prior art, the same source contact plug and drain contact plug are located at two sides of the gate structure so the source contact plug and the drain contact plug at two sides of the gate structure always have symmetric element properties.

However, with the trend of pursuing elements to be as small as possible, the intrinsic resistance within the source contact plugs and drain contact plugs due to the overly decreased critical dimension becomes too large to support the current to maintain a normal on and off state, which jeopardizes the desirable operational performance of the semiconductor elements.

A slot structure for the source contact plugs and the drain contact plugs to be disposed at two sides of the gate structure has been proposed to exhibit a symmetric layout structure. Albeit the slot layout structure seemingly reduces the total electric resistance to be able to support a larger current, serious sequels to this happen. For example, the slot structure may have serious and adverse interactions such as coupling with the gate structure. In such a way, the operational performance of the semiconductor elements does not improve at all.

In view of this, a novel semiconductor structure is still needed. Such novel semiconductor structure not only supports a larger current but also avoids some adverse consequences. In this way, problems such as overly decreased critical dimension, the extreme intrinsic resistance within the source contact plugs and drain contact plugs and deteriorated operational performance of the semiconductor elements can be thoroughly solved.

### SUMMARY OF THE INVENTION

Accordingly, the present invention proposes a novel semiconductor structure. This novel semiconductor structure not only supports a larger current but also avoids some adverse consequences. In this way, problems such as overly decreased critical dimension, the extreme intrinsic resistance within the source contact plugs and drain contact plugs and deteriorated operational performance of the semiconductor elements can be thoroughly solved.

The present invention in a first aspect proposes a semiconductor structure. The semiconductor structure of the present invention includes a substrate, a gate structure, a source, a drain, a source contact plug and a drain contact plug. The gate structure is disposed on the substrate. The source and the drain are respectively disposed in the substrate at two sides of the gate structure. The source contact plug is disposed above the source and electrically connected to the source. The drain contact plug is disposed above the drain and electrically connected to the drain. One feature of the present invention resides in the relatively asymmetric element properties of the source contact plug and the drain contact plug so that the electric resistance of the source contact plug or the drain contact plug can be decreased. The element property may be at least one of a shape, a size, a material, a stress, an aspect ratio and a quantity.

The present invention in a second aspect proposes a semiconductor structure. The semiconductor structure of the present invention includes a substrate, a gate structure, a source, a drain, a source contact plug and a drain contact plug. The gate structure is disposed on the substrate. The source and the drain are respectively disposed in the substrate at two sides of the gate structure. The source contact plug is disposed above the source and electrically connected to the source. The drain contact plug is disposed above the drain and electrically connected to the drain. Another feature of the present invention resides in the relatively asymmetric element properties of the source contact plug and the drain contact plug so that the capacitor effect of the source contact plug or the drain contact plug on the gate structure can be decreased. The element property may be at least one of a shape, a size, a material, a stress, an aspect ratio, a quantity and a distance to the gate structure. Preferably, the capacitor effect of the source contact plug on the gate structure is larger than that of the drain contact plug on the gate structure.

The present invention in a third aspect proposes a method for fabricating a semiconductor structure. First a substrate is provided. Second, a gate structure is formed on the substrate. Later, a source and a drain are respectively formed in the substrate and adjacent to the gate structure. Then, a source silicide and a drain silicide are formed in the substrate and on the source and on the drain. Afterwards, an interlayer dielectric layer is formed to cover the gate structure, the source and the drain. Next, a plurality of contact holes are formed in the interlayer dielectric layer to expose the source and the drain. Thereafter, at least a source contact plug and a drain contact plug are respectively formed in the interlayer dielectric layer and to respectively electrically connect the source and the drain. The source contact plug and the drain contact plug have at least a relatively asymmetric element property to decrease the capacitor effect of the source contact plug or of the drain contact plug on the gate structure, and/or to decrease the electric resistance of the source contact plug or the drain contact plug. The element property may be at least one of a shape, a size, a material, a stress, an aspect ratio, a distance to the gate structure and a quantity.

Because of the relatively asymmetric element properties which the source contact plug and the drain contact plug have, the capacitor effect of the source contact plug or of the drain contact plug on the gate structure can be independently adjusted, or alternatively, the electric resistance of the source contact plug or the drain contact plug can be independently adjusted as well. These modifications of the novel semiconductor structure may allow a larger operational current owing to lower electric resistance, or a minor capacitor to the gate structure without jeopardizing the original performance of the semiconductor element. In such a way, the present invention is able to practically solve problems such as overly decreased critical dimension, the extreme intrinsic resistance within the source contact plugs and drain contact plugs or deteriorated operational performance of the semiconductor elements, which the technical field currently suffers.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1 and 1A illustrates a perspective view of the semiconductor structure of the present invention.

FIG. 2 illustrates another perspective view of the semiconductor structure of the present invention.

FIGS. 3-9 illustrate a perspective view of the method for fabricating the semiconductor structure of the present invention.

### DETAILED DESCRIPTION

The present invention provides a novel semiconductor structure. The source contact plug and the drain contact plug in the light of each individual semiconductor element have at least one relatively asymmetric element property so that the element properties of the source contact plug or the drain contact plug can be independently adjusted. As a result, the capacitor effect of the source contact plug or of the drain contact plug on an individual gate structure, or the electric resistance of the source contact plug or the drain contact plug can be properly adjusted. The novel semiconductor structure of the present invention accordingly allows a larger operational current, or exhibits less capacitor to an individual gate structure to maintain an optimal performance of the semiconductor element.

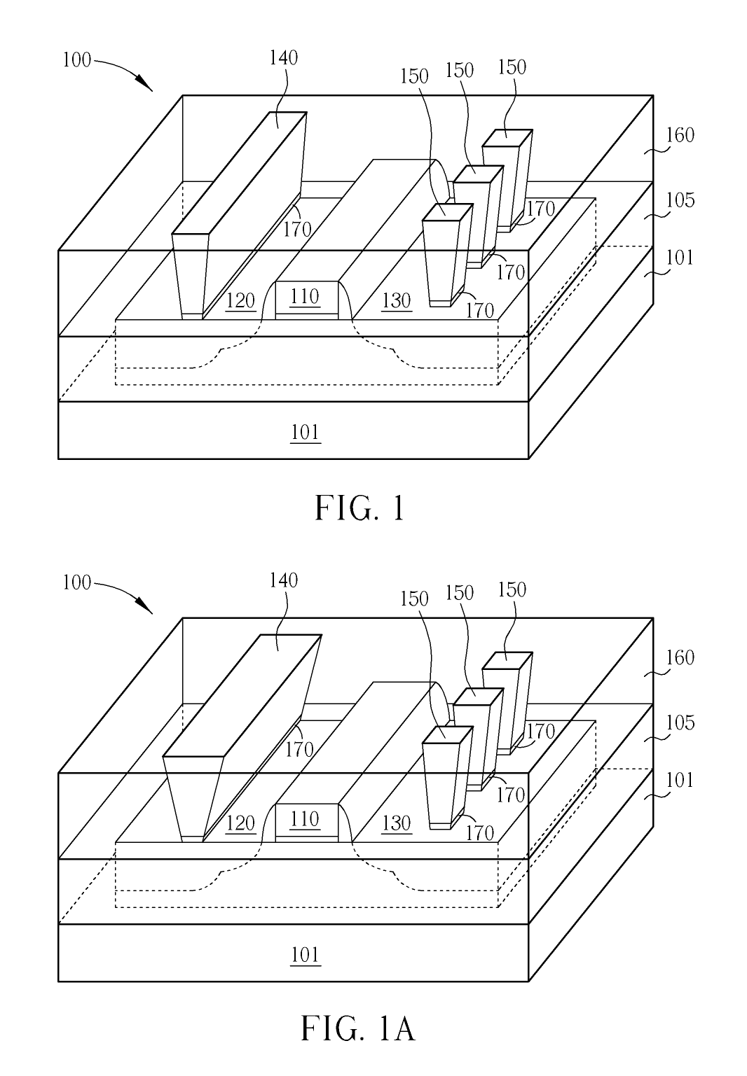

The present invention in a first aspect provides a novel semiconductor structure. FIG. 1 illustrates a perspective view of the semiconductor structure of the present invention. Please refer to FIG. 1, the semiconductor structure 100 of the present invention includes a substrate 101, a shallow trench isolation 105, a gate structure 110, a source 120, a drain 130, a source contact plug 140, a drain contact plug 150 and an interlayer dielectric layer 160. The shallow trench isolation 105 is embedded in the substrate 101. The gate structure 110 is disposed on the substrate 101 and can be a poly-Si gate or a metal gate. The gate structure 110 usually includes a gate material, a gate dielectric layer or a spacer. Optionally, the semiconductor structure 100 of the present invention may include a silicide 170 disposed between the source 120 and the source contact plug 140 as well as between the drain 130 and the drain contact plug 150. Please notice that some elements were illustrated as if they were not covered by the interlayer dielectric layer 160.

The source 120 and the drain 130 are respectively disposed in the substrate 101 at two sides of the gate structure 110. The source 120 and the drain 130 may be formed by implantation of dopants into the substrate 101 at two sides of the gate structure 101, or an epitaxial material along with dopants are filled in the recesses in the substrate 101 at two sides of the gate structure 110 in order to apply a suitable stress to the gate channel. The source contact plug 140 is disposed above the source 120, penetrates the interlayer dielectric layer 160 and is electrically connected to the source 120. The drain contact plug 150 is disposed above the drain 130, also penetrates the interlayer dielectric layer 160 and is electrically connected to the drain 130. The interlayer dielectric layer 160 is usually an insulating material or the combination of various insulating materials, such as the combination of silicon oxide, nitride, carbide, and a low-k insulating material.

One of the features of the present invention resides in that the source contact plug 140 and the drain contact plug 150 have at least one relatively asymmetric element property to decrease the electric resistance of the source contact plug 140 or to decrease the electric resistance of the drain contact plug 150. Optionally, the source contact plug 140 may have a lower electric resistance, or alternatively the drain contact plug 150 may have a lower electric resistance. However, in any case the source contact plug 140 and the drain contact plug 150 always have substantially relatively different electric resistances because the source contact plug 140 and the drain contact plug 150 have an asymmetric element property. Preferably, the source contact plug 140 may have a lower electric resistance than the drain contact plug 150.

The afore-mentioned element property may be any suitable element property, such as at least one of or some of a shape, a size, a material, a stress, an aspect ratio and a quantity of the source contact plug 140 and the drain contact plug 150. The inventors discover that with the source region, namely the source 120, the source contact plug 140 and its silicide 170, and the drain region, namely the drain 130, the drain contact plug 150 and its silicide 170, each has different responses to different design rules. When the source contact plug 140 and the drain contact plug 150 have relatively different element properties, different responses can be observed with respect to the source contact plug 140 and to the drain contact plug 150 so the desired effects may be attained. Because the source contact plug 140 and the drain contact plug 150 may have various element properties, some demonstrative examples are given here to elaborate some of possible element properties.

Shape

Optionally, the source contact plug 140 and the drain contact plug 150 may be dimensionally or geometrically asymmetric. For example, one of the source contact plug 140 and the drain contact plug 150 may be in a shape of a single square and the other may be in a shape of a slot. A slot may at least go parallel with the channel width or preferably extend to the entire source or drain so the length may be at least twice as large as the width. On the other hand, a single square may be an asymmetric layout structure that an individual gate structure has several single squares, as shown in FIG. 1. Preferably, the source contact plug 140 may be in a shape of a slot and the drain contact plug 150 may be in a shape of a single square so a source contact plug and a drain contact plug of an individual semiconductor structure construct an asymmetric layout structure.

Size

Optionally, the size of the source contact plug 140 and the drain contact plug 150 may be asymmetric. For example, one of the sizes, such as width or length, of the source contact plug 140 and the drain contact plug 150 may be larger than the other one. FIG. 1A illustrates the size of the source contact plug 140 and the drain contact plug 150 to be asymmetric. Preferably the source contact plug 140 has a larger size.

Material

Optionally, the conductive materials of the source contact plug 140 and the drain contact plug 150 may be different, so the electric resistances are different. For example, different conductive materials, such as Cu or W, are used, or they may have barrier layers of different composition or thickness.

Stress

Optionally, the source region and the drain region may generate different stress on the gate structure 110. Different ways may be used to generate different stress. For example, different epitaxial materials along with dopants are filled in the recesses which are formed in the source region and the drain region, or either one recess is filled to generate different stress to the gate structure 110. On the other hand, the bottoms of the source contact plug 140 and the drain contact plug 150 may extend into the epitaxial materials to be lower than the gate dielectric layer in the gate structure 110. In addition, to adjust the thickness ratio of the barrier layer to the plug material, or to adjust the formation parameters of the barrier layer, such as physical vapor deposition (PVD), chemical vapor deposition (CVD), temperature or pressure . . . etc. may also adjust the needed stress.

Or, a stress layer, such as a contact etching-stop layer, may be optionally used to cover the gate structure 110 to generate different stress. At the moment, the bottoms of the source contact plug 140 and the drain contact plug 150 may penetrate the stress layer. Of course, the source contact plug 140 and the drain contact plug 150 may respectively penetrate the stress layer in an asymmetric way, such as different shapes or sizes of the openings, to accomplish the feature of asymmetric element property of the present invention.

Aspect Ratio

Optionally, the aspect ratios of the source contact plug 140 and the drain contact plug 150 may be asymmetric. For example, the sizes of the openings of the contact holes for preparing the source contact plug 140 and the drain contact plug 150 may be different so that the aspect ratios of the two are asymmetric. Or for instance, the contact plugs may include a plug material, namely a conductive material and a barrier material or a plug material, namely a conductive material alone. The barrier material may be Ti, TiN or the combination thereof.

Quantity

Optionally, the quantity of the source contact plug 140 and the drain contact plug 150 may be asymmetric. For example, one is more than the other. FIG. 1 illustrates there are several drain contact plugs 150 but there is only one source contact plug 140.

In any case, the electric resistance of the source contact plug 140 and the drain contact plug 150 is substantially distinctive as long as the source contact plug 140 and the drain contact plug 150 have a relatively asymmetric element property so the present invention is able to practically solve problems such as overly decreased critical dimension, the extreme intrinsic resistance within the source contact plugs and drain contact plugs or deteriorated operational performance of the semiconductor elements, which the technical field currently suffers.

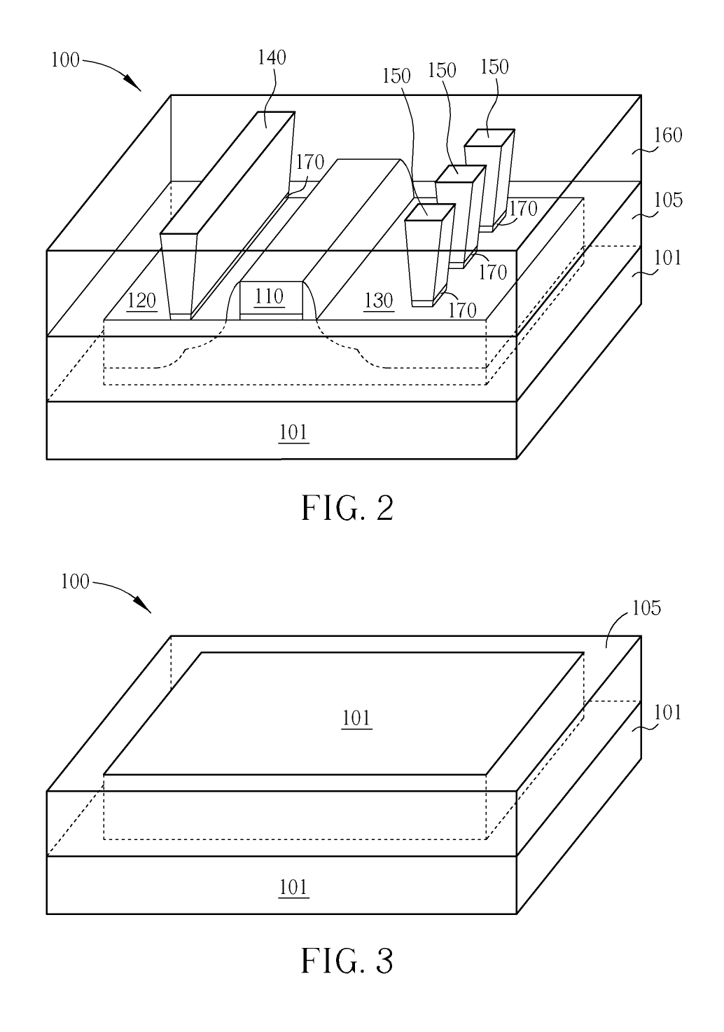

The present invention in a second aspect provides another semiconductor structure. FIG. 2 illustrates another perspective view of the semiconductor structure of the present invention. Please refer to FIG. 2. The semiconductor structure 100 of the present invention includes a substrate 101, a shallow trench isolation 105, a gate structure 110, a source 120, a drain 130, a source contact plug 140, a drain contact plug 150 and an interlayer dielectric layer 160. The shallow trench isolation 105 is embedded in the substrate 101. The gate structure 110 is disposed on the substrate 101 and can be a poly-Si gate or a metal gate. The gate structure 110 usually includes a gate material, a gate dielectric layer or a spacer. Optionally, the semiconductor structure 100 of the present invention may include a silicide 170 disposed between the source 120 and the source contact plug 140 as well as between the drain 130 and the drain contact plug 150. Please notice that some elements were illustrated as if they were not covered by the interlayer dielectric layer 160.

The source 120 and the drain 130 are respectively disposed in the substrate 101 at two sides of the gate structure 110. The source 120 and the drain 130 may be formed by implantation of dopants into the substrate 101 at two sides of the gate structure 110, or an epitaxial material along with dopants are filled in the recesses in the substrate 101 at two sides of the gate structure 110 in order to apply a suitable stress to the gate channel. The source contact plug 140 is disposed above the source 120, penetrates the interlayer dielectric layer 160 and is electrically connected to the source 120. The drain contact plug 150 is disposed above the drain 130, also penetrates the interlayer dielectric layer 160 and is electrically connected to the drain 130. The interlayer dielectric layer 160 is usually an insulating material, such as silicon oxide.

One of the features of the present invention resides in that the source contact plug 140 and the drain contact plug 150 have at least one relatively asymmetric element property to adjust the capacitor effect of the source contact plug 140 on the gate structure 110 or the capacitor effect of the drain contact plug 150 on the gate structure 110 to reach an optimal result. Optionally, the source contact plug 140 may have less capacitor effect on the gate structure 110, or alternatively the drain contact plug 150 may have less capacitor effect on the gate structure 110. However, in any case the source contact plug 140 and the drain contact plug 150 always have substantially different effect on the gate structure 110 because the source contact plug 140 and the drain contact plug 150 have an asymmetric element property. Preferably, the drain contact plug 150 has less capacitor effect on the gate structure 110 than the source contact plug 140 to the gate structure 110.

The afore-mentioned element property may be any suitable element property, such as at least one of or some of a shape, a size, a material, a stress, an aspect ratio, a quantity and a distance to the gate structure 110 of the source contact plug 140 and the drain contact plug 150. The inventors discover that with the source region, namely the source 120, the source contact plug 140 and its silicide 170, and the drain region, namely the drain 130, the drain contact plug 150 and its silicide 170, each has different responses to different design rules. When the source contact plug 140 and the drain contact plug 150 have different element properties, different responses can be observed with respect to the source contact plug 140 and to the drain contact plug 150 so the desired effects may be attained. Because the source contact plug 140 and the drain contact plug 150 may have various element properties, some demonstrative examples are given here to elaborate some of possible element properties.

Distance

Optionally, the distance to the gate structure 110 from the source contact plug 140 and from the drain contact plug 150 may be asymmetric. Generally speaking, a greater distance means less capacitor effect. For example, one of the source contact plug 140 and the drain contact plug 150 may have a relatively greater distance to the gate structure 110 and the other may have a relatively shorter distance to the gate structure 110 to get the desired effects. FIG. 2 illustrates that the source contact plug 140 is closer to the gate structure 110 and the drain contact plug 150 is more distant to the gate structure 110 to get an asymmetric element property.

Other properties such as shape, size, material, stress, aspect ratio and quantity may refer to the above corresponding descriptions. In any case, the capacitor effect of the source contact plug 140 on the gate structure 110 or the capacitor effect of the drain contact plug 150 on the gate structure 110 is substantially distinctive as long as the source contact plug 140 and the drain contact plug 150 have an asymmetric element property so the present invention is able to practically solve problems such as overly decreased critical dimension, the adverse capacitor effect of the source contact plug 140 and of the drain contact plug 150 on the gate structure or deteriorated operational performance of the semiconductor elements, which the technical field currently suffers.

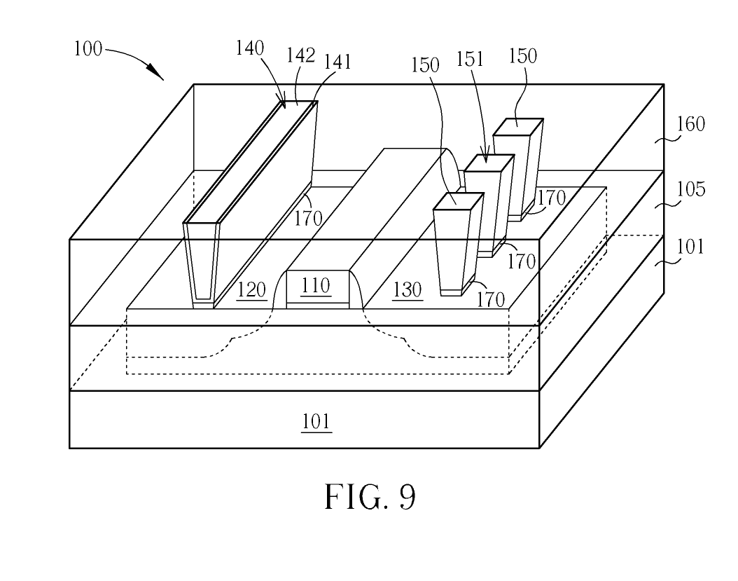

The present invention in a third aspect provides a method for fabricating a semiconductor structure. FIGS. 3-9 illustrate a perspective view of the method for fabricating the semiconductor structure of the present invention. Please notice that some elements were illustrated as if they were not covered by the interlayer dielectric layer.

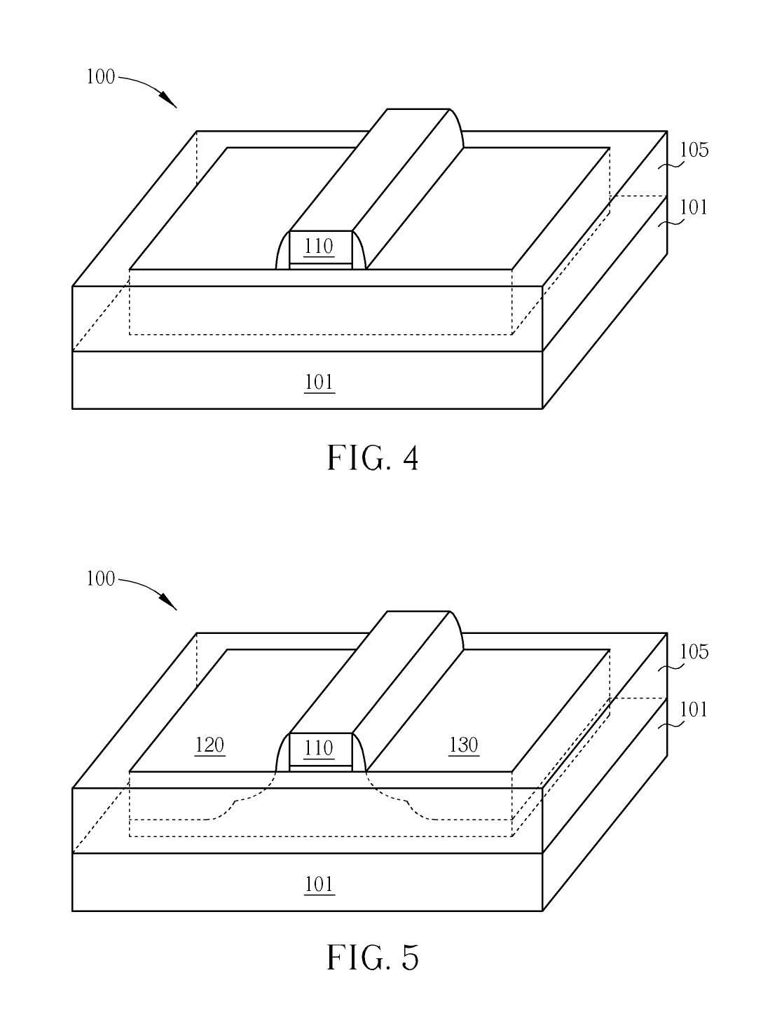

First, please refer to FIG. 3, a substrate 101, such as a semiconductor substrate is provided. There are doped wells or shallow trench isolation 105 in the substrate 101. Second, please refer to FIG. 4, a gate structure 110 is formed. The gate structure 110 is disposed on the substrate 101 and may be formed by conventional steps. The gate structure 110 may be a poly-Si gate or a metal gate. The gate structure 110 usually includes a gate material, a gate dielectric layer or a spacer.

Later, as shown in FIG. 5, a set of source 120 and a drain 130 are respectively formed in the substrate 101 and adjacent to the gate structure 110. The source 120 and the drain 130 may be formed by various ways. For example, the source 120 and the drain 130 may be formed by implantation of dopants into the substrate 101 at two sides of the gate structure 101 and optionally include a lightly doped region or a heavily doped region. Or, recesses are first formed in the substrate 101 at two sides of the gate structure 101, then an epitaxial material along with dopants are epitaxially filled in the recesses in order to apply a suitable stress to the gate channel.

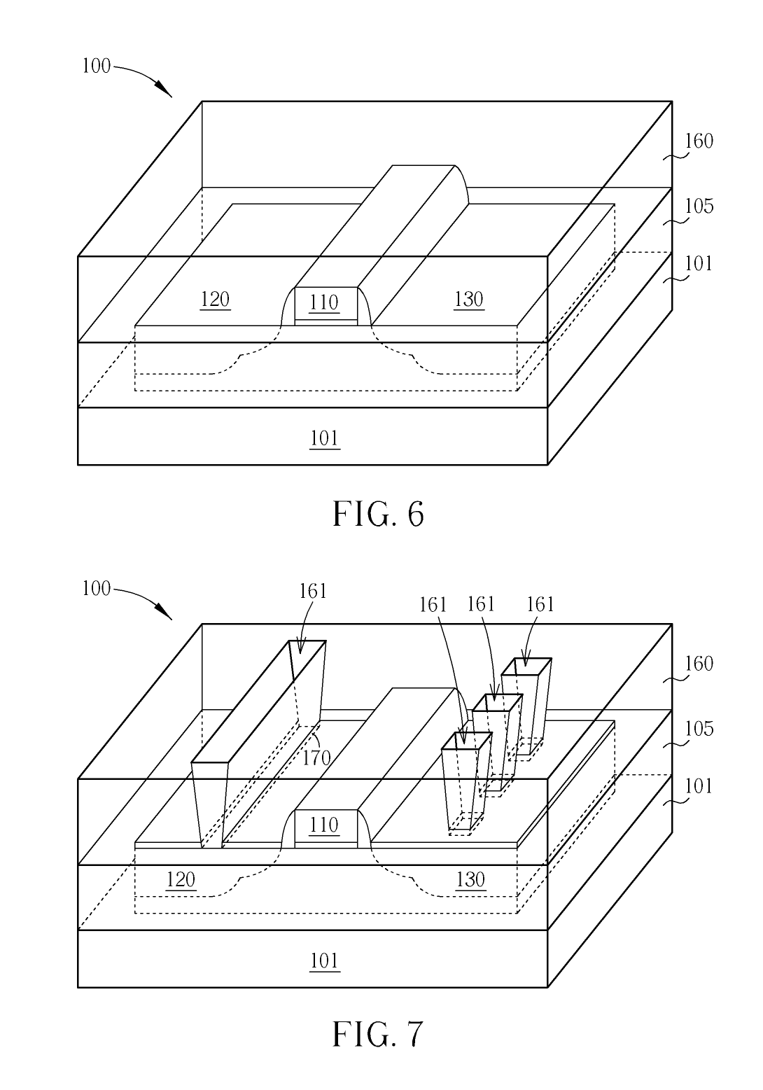

Afterwards, as shown in FIG. 6, an interlayer dielectric layer 160 is formed on the gate structure 110, the source 120 and the drain 130. The interlayer dielectric layer 160 may directly cover the gate structure 110, the source 120 and the drain 130. The interlayer dielectric layer 160 is usually an insulating material or various insulating materials, such as the combination of silicon oxide, nitride, carbide, and a low-k insulating material.

Next, as shown in FIG. 7, multiple contact holes 161 are formed in the interlayer dielectric layer 160. They expose the source 120 and the drain 130 of one single semiconductor element. For example, a photoresist (not shown) may go with lithographic and etching steps to remove some of the interlayer dielectric layer 160 to form multiple contact holes 161. Conventionally a contact etching-stop layer 162 (CESL) may be formed before the interlayer dielectric layer 160 is formed on the gate structure 110, the source 120 and the drain 130. At the moment, the contact etching-stop layer 162 may serve as a stress layer. A stress layer may cover the gate structure 110 to generate an appropriate stress.

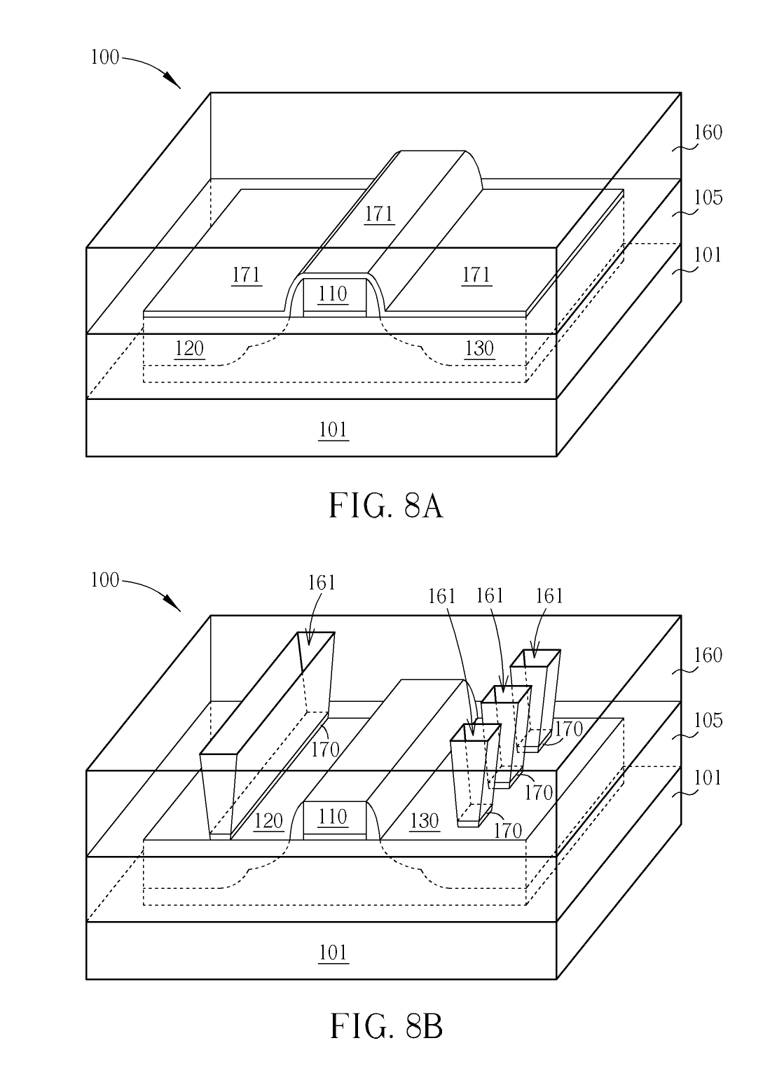

Optionally, a source silicide/drain silicide 170 may be formed before or after multiple contact holes 161 are formed to be respectively disposed in the substrate 101 and on the source 120 and on the drain 130. If the source silicide/drain silicide 170 are formed on the source 120 and on the drain 130 before multiple contact holes 161 are formed, a suitable metal 171 is used to entirely cover the substrate 101, the gate structure 110, the source 120 and the drain 130 before the contact etching-stop layer 162 and the interlayer dielectric layer 160 are formed, as shown in FIG. 8A. Later a thermo step is carried out to make the exposed silicon atoms react with the metal to form the source silicide/drain silicide 170.

Or alternatively, a suitable metal is used to fill the contact holes 161 after multiple contact holes 161 are formed if the source silicide/drain silicide 170 are formed on the source 120 and on the drain 130 after multiple contact holes 161 are formed. Later, a thermo step is carried out to make the exposed silicon atoms react with the metal to form the source silicide/drain silicide 170, as shown in FIG. 8B.

Thereafter, at least a source contact plug 140 and a drain contact plug 150 are formed in the interlayer dielectric layer 160 to respectively electrically connect the source 120 and the drain 130. The source contact plug 140 and the drain contact plug 150 have at least one asymmetric element property. If the contact etching-stop layer 162 is present, the source contact plug 140 and the drain contact plug 150 penetrate the contact etching-stop layer 162 and the source contact plug 140 and the drain contact plug 150 still have the asymmetric element property.

The afore-mentioned element property may be any suitable element property, such as at least one of or some of a shape, a size, a material, a stress, an aspect ratio, a quantity and a distance to the gate structure 110 of the source contact plug 140 and the drain contact plug 150. The inventors discover that with the source region, namely the source 120, the source contact plug 140 and its silicide 170, and the drain region, namely the drain 130, the drain contact plug 150 and its silicide 170, each has different responses to different design rules. When the source contact plug 140 and the drain contact plug 150 have asymmetric element properties, different responses can be observed with respect to the source contact plug 140 and to the drain contact plug 150 so the desired effects may be attained. Because the source contact plug 140 and the drain contact plug 150 may have various asymmetric element properties, some demonstrative examples are given here to elaborate some of possible element properties.

Distance

Optionally, when a photoresist (not shown) is used to go with lithographic and etching steps to form multiple contact holes 161, the layout pattern on the reticle may be designed to control the relative position between the contact holes 161 and the gate structure 110 so the distance to the gate structure 110 from the source contact plug 140 and from the drain contact plug 150 are asymmetric. FIG. 7 illustrates that the contact etching-stop layer 162 is present and the source contact plug 140 is closer to the gate structure 110 and the drain contact plug 150 is more distant to the gate structure 110 to get an asymmetric element property.

Shape

Optionally, when a photoresist (not shown) is used to go with lithographic and etching steps to form multiple contact holes 161, the layout pattern on the reticle may be designed to control the contact holes 161 to be asymmetric, so the resultant source contact plug 140 and the drain contact plug 150 may be dimensionally or geometrically asymmetric, as shown in FIG. 7. Preferably, the source contact plug 140 may be in a shape of a slot.

Size

Optionally, when a photoresist (not shown) is used to go with lithographic and etching steps to form multiple contact holes 161, the layout pattern on the reticle (not shown) may be designed to control the sizes of the contact holes 161 to be asymmetric, so the resultant size of the source contact plug 140 and the drain contact plug 150 are asymmetric. FIG. 1A illustrates the size of the source contact plug 140 to be larger.

Material

Optionally, the plug materials for filling contact holes 161 may be different, so the resultant electric resistances of the source contact plug 140 and the drain contact plug 150 are different. For example, different conductive materials, such as Cu or W, are used.

Stress

Optionally, the source region and the drain region may generate different stress on the gate structure 110. For example, different epitaxial materials or dopants are used. Or, a stress layer, such as a contact etching-stop layer, may be optionally used to cover the gate structure 110 to generate different stress.

Aspect Ratio

Optionally, the aspect ratios of the source contact plug 140 and the drain contact plug 150 may be asymmetric. For example, the sizes of the openings of the contact holes for preparing the source contact plug 140 and the drain contact plug 150 may be different, or the materials in the contact holes may be different, so that the aspect ratios of the two are asymmetric.

Quantity

Optionally, the quantity of the source contact plug 140 and the drain contact plug 150 may be asymmetric. For example, one is more than the other. FIG. 1 illustrates there are several drain contact plugs 150 but there is only one source contact plug 140.

In any case, the electric resistance of the source contact plug 140 and the drain contact plug 150 or the capacitor effect on the gate structure 110 is substantially distinctive as long as the source contact plug 140 and the drain contact plug 150 have asymmetric element properties so the present invention is able to practically solve problems such as overly decreased critical dimension, the extreme intrinsic resistance within the source contact plugs and drain contact plugs or deteriorated operational performance of the semiconductor elements, which the technical field currently suffers.

Those skilled in the art will readily observe that numerous modifications and alterations of the device and method may be made while retaining the teachings of the invention.

What is claimed is:

1. A semiconductor structure, comprising:
a substrate;
a gate structure disposed on said substrate;
a source and a drain respectively disposed in said substrate at two sides of said gate structure;
a source contact plug disposed above said source and electrically connected to said source; and
a drain contact plug disposed above said drain and electrically connected to said drain, wherein said source contact plug and said drain contact plug have an relatively asymmetric element property to decrease an electric resistance of one of said source contact plug and said drain contact plug.

2. The semiconductor structure of claim 1, wherein said element property comprises at least one of a shape, a size, a material, a stress, an aspect ratio and a quantity.

3. The semiconductor structure of claim 1, wherein one of said source contact plug and said drain contact plug is in a shape of a single square and the other is in a shape of a slot.

4. The semiconductor structure of claim 1, wherein at least one of height, length and width of said source contact plug and said drain contact plug is different.

5. The semiconductor structure of claim 1, wherein at least one of said source contact plug and said drain contact plug comprises at least two plug materials which are selected from a conductive material and a barrier material.

6. The semiconductor structure of claim 5, wherein said source contact plug and said drain contact plug have different thickness ratios of said conductive material to said barrier material.

7. The semiconductor structure of claim 1, wherein at least one of said source and said drain has an epitaxial structure comprising Si and other materials.

8. A semiconductor structure, comprising:
a substrate;
a gate structure disposed on said substrate;
a source disposed in said substrate and adjacent to said gate structure;
a source contact plug disposed above said source and electrically connected to said source;
a drain disposed in said substrate and adjacent to said gate structure; and
a drain contact plug disposed above said drain and electrically connected to said drain, wherein said source contact plug and said drain contact plug have an relatively asymmetric element property to decrease a capacitor effect of one of said source contact plug and said drain contact plug with respect to said gate structure.

9. The semiconductor structure of claim 8, wherein said element property comprises at least one of a shape, a size, a material, a stress, an aspect ratio, a quantity and a distance to said gate structure.

10. The semiconductor structure of claim 8, wherein one of said source contact plug and said drain contact plug is in a shape of a slot and the other is in a shape of a single square.

11. The semiconductor structure of claim 8, wherein at least one of height, length and width of said source contact plug and said drain contact plug is different.

12. The semiconductor structure of claim 8, wherein at least one of said source contact plug and said drain contact plug comprises at least two plug materials which are selected from a conductive material and a barrier material.

13. The semiconductor structure of claim 12, wherein said source contact plug and said drain contact plug have different thickness ratios of said conductive material to said barrier material.

14. The semiconductor structure of claim 1, wherein at least one of said source and said drain has a recessed structure.

15. A method for fabricating a semiconductor structure, comprising:
providing a substrate;
forming a gate structure disposed on said substrate;
forming a source and a drain respectively disposed in said substrate and adjacent to said gate structure;
forming a source silicide and a drain silicide respectively disposed in said substrate and disposed on said source and on said drain;
forming an interlayer dielectric layer to cover said gate structure, said source and said drain;
forming a plurality of contact holes in said interlayer dielectric layer to expose said source and said drain;
forming at least a source contact plug and a drain contact plug respectively disposed in said interlayer dielectric layer to respectively electrically connect said source and said drain, wherein said source contact plug and said drain contact plug have an relatively asymmetric element property to decrease at least one of an electric resistance of one of said source contact plug and of said drain contact plug, and a capacitor effect of one of said source contact plug and of said drain contact plug with respect to said gate structure.

16. The method for fabricating a semiconductor structure of claim 15, wherein forming said interlayer dielectric layer is performed before forming said source silicide and said drain silicide.

17. The method for fabricating a semiconductor structure of claim 15, wherein forming said interlayer dielectric layer is performed after forming said source silicide and said drain silicide.

18. The method for fabricating a semiconductor structure of claim 15, wherein at least one of a conductive layer and a barrier layer is formed in at least one of said contact holes to form at least one of said source contact plug and said drain contact plug.

19. The method for fabricating a semiconductor structure of claim 18, wherein a stress is adjusted by adjusting a thickness ratio of said conductive layer to said barrier layer.

20. The method for fabricating a semiconductor structure of claim 18, wherein at least one of a physical vapor deposition (PVD) and a chemical vapor deposition (CVD) is used to form said barrier layer under a suitable temperature and a suitable pressure.

21. The method for fabricating a semiconductor structure of claim 15, wherein said element property comprises at least one of a shape, a size, a material, a stress, an aspect ratio and a quantity.

22. The method for fabricating a semiconductor structure of claim 15, wherein one of said source contact plug and said drain contact plug is in a shape of a single square and the other is in a shape of a slot.

23. The method for fabricating a semiconductor structure of claim 15, wherein at least one of height, length and width of said source contact plug and said drain contact plug is different.

24. The method for fabricating a semiconductor structure of claim 15, wherein at least one of said source contact plug and said drain contact plug comprises at least two plug materials which are selected from a conductive material and a barrier material.

25. The method for fabricating a semiconductor structure of claim 15, wherein at least one of said source and said drain has an epitaxial structure comprising Si and other materials.
